(19) United States
(12) Patent Application Publication
(10) Pub. No.: US 2010/0118477 A1
(43) Pub. Date: May 13, 2010

(54) POWER SUPPLY DEVICE

(75) Inventors: XIN-QUAN ZHOU, Shenzhen City (CN); HSIAO-HUA TU, Taipei (TW); YE LIU, Shenzhen City (CN); GANG YANG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/578,160

(22) Filed: Oct. 13, 2009

(30) Foreign Application Priority Data
Nov. 12, 2008 (CN) 200810305494.9

(51) Int. Cl. H05K 5/00

(52) U.S. Cl. 361/679.01

(57) ABSTRACT

A power supply device is provided as an accessory to a portable electronic device to supply electric power to the portable electronic device. The power supply device includes a shell and a battery. The shell defines a concave assembling portion for assembling the portable electronic device therein and is configured to provide a better viewing angle of the portable electronic device. The battery is assembled within the shell to supply electric power.

### BACKGROUND

1. Technical Field

The exemplary disclosure generally relates to a power supply device for a portable electronic device.

2. Description of Related Art

With the development of wireless communication and information processing technology, portable electronic devices, such as mobile telephones and personal digital assistants (PDAs) are now in widespread use. These electronic devices enable consumers to enjoy the convenience of high technology services, anytime and at virtually any location. Nowadays, the portable electronic devices with television broadcast function have become more popular.

However, the power capacity of the existing battery assembled within the portable electronic device cannot satisfy the long time use of the television broadcast function of the portable electronic device. It is necessary to provide an external power supply device to supply enough electric power to the portable electronic device to withstand a high level of energy consumption when using the television broadcast function.

Therefore, there is room for improvement within the art.

### BRIEF DESCRIPTION OF THE DRAWINGS

Many aspects of the exemplary power supply device can be better understood with reference to the following drawings. These drawings are not necessarily drawn to scale, the emphasis instead being placed upon clearly illustrating the principles of the present power supply device. Moreover, in the drawings like reference numerals designate corresponding parts throughout the several views. Wherever possible, the same reference numbers are used throughout the drawings to refer to the same or like elements of an embodiment.

FIG. 1 shows a disassembled perspective view of a power supply device according to an exemplary embodiment, wherein a portable electronic device is assembled thereto.

FIG. 2 shows a perspective view of the power supply device, wherein the portable electronic device is assembled to the power supply device.

FIG. 3 is similar to FIG. 2, but viewed from another aspect.

### DETAILED DESCRIPTION

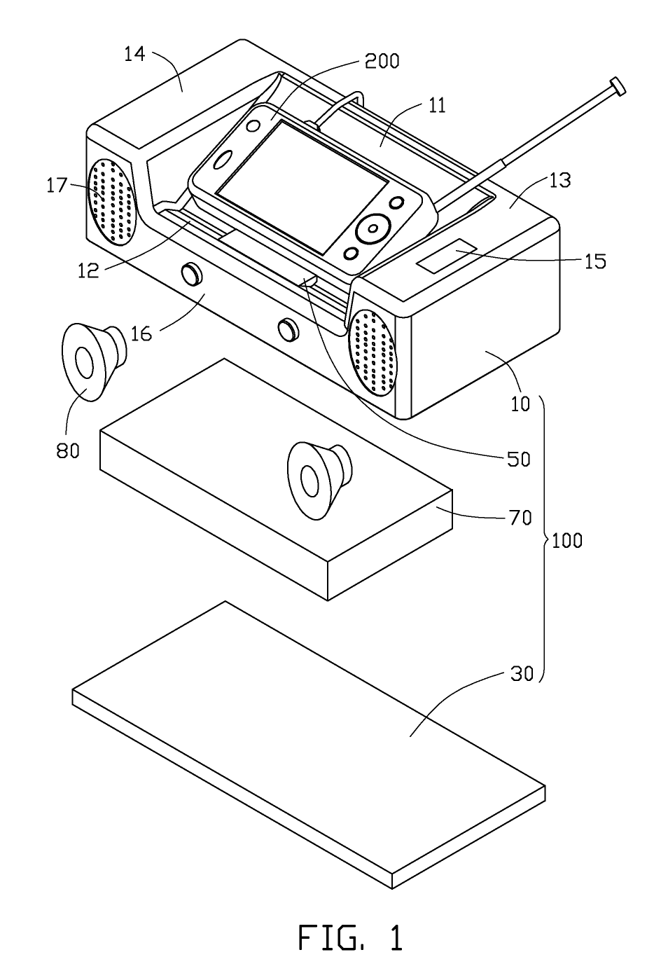

FIG. 1 shows a disassembled perspective view of a power supply device 100 configured to assemble and supply electric power to a portable electronic device 200. The portable electronic device 200 can be a mobile telephone, a personal digital assistant (PDA), etc. with television broadcast function. The portable electronic device 200 includes a main body 201 and an antenna 203 assembled to the main body 201. The antenna 203 electrically connects with the main body 201 and is configured to search and receive TV signals.

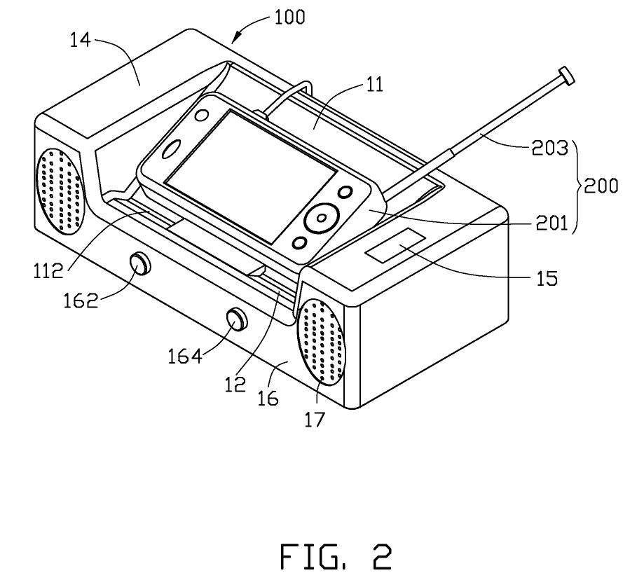

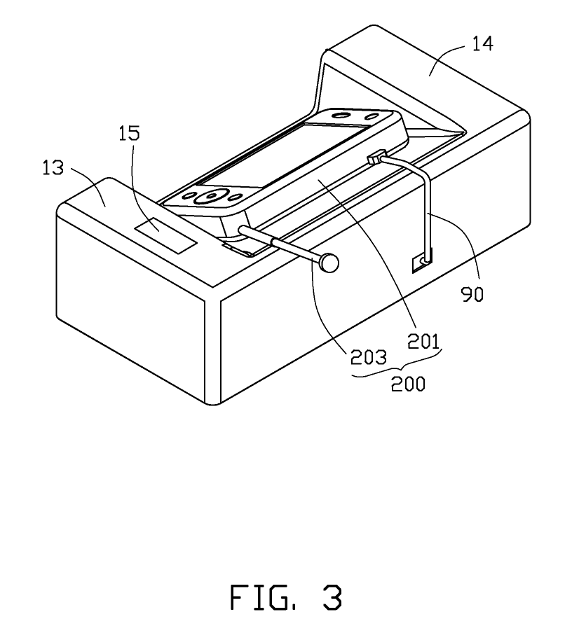

FIG. 2 and FIG. 3 show two perspective views of the power supply device 100 with the portable electronic device 200 assembled thereto for supplying electric power to the portable electric device 200. The power supply device 100 includes a shell 10, a cover 30, a stopper 50, a battery 70 and two speakers 80. In the exemplary embodiment, the shell 10 is substantially rectangular hollow shape. The shell 10 includes a top wall 13 and a sidewall 16 perpendicular to the top wall 13. The top wall 13 is recessed toward the sidewall 16 to form a portion of a concave assembling portion (not labeled). The concave assembling portion also communicates with the sidewall 16 and includes a first inclined bottom surface 11, a second inclined bottom surface 12, and two side protrusions 14 formed at two sides of the assembling portion respectively.

The first inclined bottom surface 11 is configured to be inclined toward the sidewall 16 to support the portable electronic device 200 assembled therein and form a better viewing angle of the portable electronic device 200. The first inclined bottom surface 11 forms an obtuse angle of about 100 to 150 degrees with the horizontal. Preferably, the first inclined bottom surface 11 forms a substantially 120 degree angle with the horizontal plane parallel to the top wall 13. The second inclined bottom surface 12 connects with the first inclined bottom surface 11 and is configured to be inclined in a direction opposite to/away from the first inclined bottom surface 11. Thus, the second inclined bottom surface 12 forms a substantially V-shaped groove 112 together with the first inclined bottom surface 11.

The top wall 13 further includes at least one slot 15 defined thereon surrounding the assembling portion for assembling some lighting units (e.g. background lights, fluorescent lamps, floodlights, etc.) therein, to provide light during functioning of the portable electronic device 200. The two side protrusions 14 are hollow and configured to assemble the two speakers 80 therein.

The sidewall 16 defines several through holes 17 therethrough at the two ends thereof corresponding to the two protrusions 14 respectively, for transmitting sound generated by the speakers 80 out. The sidewall 16 further includes a first operating button 162 and a second operating button 164 spaced disposed at a substantially middle portion thereof. The first operating button 162 can be a power switch for turning on or turning off the power supply to the portable electronic device 200. The second operating button 164 can be a volume adjusting button configured to adjust and control the volume of the speakers 80.

The cover 30 is detachably assembled to the shell 10 for packaging or enclosing the battery 70, the speakers 80, etc. within the shell 10.

The stopper 50 is made of elastic material such as plastic and has a shape corresponding to the V-shaped groove 112 for being fixedly assembled within the V-shaped groove 112. The stopper 50 is configured to maintain the portable electronic device 200 in position within the assembling portion of the shell 10 to achieve a better viewing angle of the portable electronic device 200 and to prevent the portable electronic device 200 from sliding relative to the first inclined bottom surface 11.

The battery 70 is assembled within the shell 10 to supply the electric power to the portable electronic device 200. The battery 70 has a large electric power capacity and electrically connects with the portable electronic device 200 by a data wire 90. It is to be understood that the battery 70 can be a chargeable battery, an accumulator, a storage battery, a battery pack, etc., and can be used repeatedly. The two speakers 80 are assembled within the shell 10 corresponding to the two side protrusions 14 respectively, and are configured to receive the audio signals of the portable electronic device 200 and magnify the sound of the portable electronic device 200 via the data wire 90.

In use, the portable electronic device 200 is assembled to the power supply device 100 and is accommodated within the assembling portion of the shell 10. One side of the portable electronic device 200 is leant back on/laid on the first inclined bottom surface 11 and is resisted by the stopper 50. The portable electronic device 200 is electrically connected to the power supply device 100 by the data wire 90. The first operating button 162 of the power supply device 100 is turned on to supply the electric power to the portable electronic device 200, and the portable electronic device 200 is operated to use the Television broadcast function. The speakers 80 assembled within the power supply device 100 and the lighting units assembled within the slot 15 cooperatively work together to enhance the television broadcast effect. The second operating button 164 is operated to adjust the volume of the speakers 80.

It is to be understood that the power supply device 100 may further includes an external plug configured to be electrically connected to an electrical socket for charging the battery 70 of the power supply device 100 or supplying the electric power.

The exemplary power supply device 100 is provided as an accessory attached to the portable electronic device 200 with television broadcast function, to supply enough electronic power to the portable electronic device 200. The power supply device 100 affords/ensures the long time use need of the portable electronic device 200 efficiently. The power supply device 100 is multifunctional and is configured as a musical box and a supporting pedestal.

It is to be understood, however, that even through numerous characteristics and advantages of the present invention have been set forth in the foregoing description, together with details of the structure and function of the invention, the disclosure is illustrative only, and changes can be made in detail, especially in matters of shape, size, and arrangement of parts within the principles of the invention to the full extent indicated by the broad general meaning of the terms in which the appended claims are expressed.

What is claimed is:

1. A power supply device configured as an independent power supplier to supply electric power to a portable electronic device, comprising:
a shell defining a concave assembling portion for assembling the portable electronic device therein; wherein, the concave assembling portion comprises a first inclined bottom surface configured to provide a better viewing angle of the portable electronic device; and
a battery assembled within the shell and configured to supply electric power to the portable electronic device.

2. The power supply device as claimed in claim 1, wherein the shell includes a top wall and a sidewall; the concave assembling portion is formed by recessing from the top wall toward the sidewall and communicates with the sidewall.

3. The power supply device as claimed in claim 2, wherein the assembling portion further includes a second inclined bottom surface, and two side protrusions disposed at the two sides of the assembling portion respectively; the second inclined bottom surface forms a substantially V-shaped groove together with the first inclined bottom surface; the portable electronic device leans against the first inclined bottom surface and is maintained in position by the second inclined bottom surface.

4. The power supply device as claimed in claim 3, wherein the first inclined bottom surface is configured to be inclined toward the sidewall to support the portable electronic device and form the better viewing angle of the portable electronic device; the first inclined bottom surface forms an obtuse angle with the top wall; the second inclined bottom surface connects with the first inclined bottom surface and is configured to be inclined in a direction away from the first inclined bottom surface.

5. The power supply device as claimed in claim 4, wherein the first inclined bottom surface forms a substantially 100-150 degree angle with the horizontal plane.

6. The power supply device as claimed in claim 1, wherein the battery electrically connects with the portable electronic device by a data wire; the battery is an accumulator, a storage battery or a battery pack configured for being reused multiple times.

7. The power supply device as claimed in claim 3, wherein the power supply device further includes a stopper, the stopper is fixedly assembled within the V-shaped groove and is configured to resist the portable electronic device assembled within the assembling portion of the shell and to prevent the portable electronic device from sliding relative to the first inclined bottom surface.

8. The power supply device as claimed in claim 7, wherein the two side protrusions are hollow configured; the power supply device further includes two speakers assembled within the corresponding two side protrusions respectively; the sidewall defines several through holes therethrough at the two ends thereof corresponding to the two protrusions for transmitting there through the sound produced by the speakers.

9. The power supply device as claimed in claim 8, wherein the sidewall further includes a first operating button and a second operating button disposed thereon; the first operating button being a power switch; the second operating button being a volume adjusting button.

10. The power supply device as claimed in claim 8, wherein the power supply device further includes a cover detachably assembled to the shell for packaging or enclosing the battery and the speaker within the shell.

11. The power supply device as claimed in claim 4, wherein the top wall further includes at least one slot defined thereon surround the assembling portion for assembling some lighting units therein, to provide a lighting effect when the portable electronic device is being used.

12. A power supply device comprising:
a shell defining a concave assembling portion for assembling a portable electronic device therein; wherein, the concave assembling portion comprises a first inclined bottom surface configured to provide a better viewing angle of the portable electronic device; and
a battery assembled within the shell and configured to supply electric power to the portable electronic device; and
two speakers assembled within the shell to receive and play the audio signals of the portable electronic device of the portable electronic device.

13. The power supply device as claimed in claim 12, wherein the assembling portion further includes a second inclined bottom surface forming a substantially V-shaped groove with the first inclined bottom surface; the power supply device further includes a stopper fixedly assembled within the V-shaped groove; the portable electronic device leans against the first inclined bottom surface and is maintained in position by the stopper.

14. The power supply device as claimed in claim 13, wherein the power supply device further includes a cover detachably assembled to the shell for packaging or enclosing the battery and the speaker within the shell.

15. The power supply device as claimed in claim 13, wherein the first inclined bottom surface forms an obtuse angle from about 100 to 150 degrees with the horizontal plane.
